(19) United States
(12) Patent Application Publication
(10) Pub. No.: US 2026/0082941 A1
(43) Pub. Date: Mar. 19, 2026

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Tsung-Yu Chen, Hsinchu City (TW); Wensen Hung, Hsinchu County (TW); Jung-Wei Cheng, Hsinchu City (TW)

(73) Assignee: Taiwan Semiconductor Manufacturing Company, Ltd., Hsinchu (TW)

(21) Appl. No.: 18/889,397

(22) Filed: Sep. 19, 2024

(51) Int. Cl. H01L 23/495; H01L 23/367; H01L 23/373

(52) U.S. Cl. CPC H10W 70/461; H10W 40/228; H10W 40/253; H10W 70/417

(57) ABSTRACT

A semiconductor package includes a substrate, a die, a first bonding material, a second bonding material and a heat dissipation system. The die is connected to the substrate. The first bonding material is disposed on the substrate beside the die. The second bonding material is disposed on and covers the die. The heat dissipation system, having a bottom surface in contact with the second bonding material, is disposed on the second bonding material over the die and on the first bonding material on the substrate. The heat dissipation system is fixed to the substrate through the first bonding material. The bottom surface of the heat dissipation system is fixed to the die through the second bonding material with a bonding interface existing therebetween, and the bonding interface includes a first curved surface.

### BACKGROUND

Advanced packaging and assembling techniques integrate multiple semiconductor dies and electronic components into package structures. Following miniaturization trend of electronic products, heat dissipation of the packaged semiconductor dies has become an important issue for packaging technology.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 through FIG. 5 are schematic cross-sectional views illustrating intermediate structures formed at various stages of a manufacturing method of a semiconductor package according to some embodiments of the present disclosure.

FIG. 6 is a schematic planar view illustrating the semiconductor package according to some embodiments of the present disclosure.

FIG. 7 is a schematic bottom view showing a heat dissipation system according to some embodiments of the present disclosure.

FIG. 8 and FIG. 9 illustrate various portions of the heat dissipation system before assembly according to some embodiments of the present disclosure.

FIG. 10 illustrates the skived fins within the heat dissipation system according to some embodiments of the present disclosure.

FIG. 11A through FIG. 11F are schematic cross-sectional views of flexible pillars within the heat dissipation system according to some embodiments of the present disclosure.

FIG. 12 is a schematic cross-sectional view showing an electronic device according to some embodiments of the present disclosure.

FIG. 13 is a schematic cross-sectional view showing another electronic device according to some embodiments of the present disclosure.

FIG. 14 is a schematic cross-sectional view of a semiconductor package according to some embodiments of the present disclosure.

### DESCRIPTION OF THE EMBODIMENTS

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

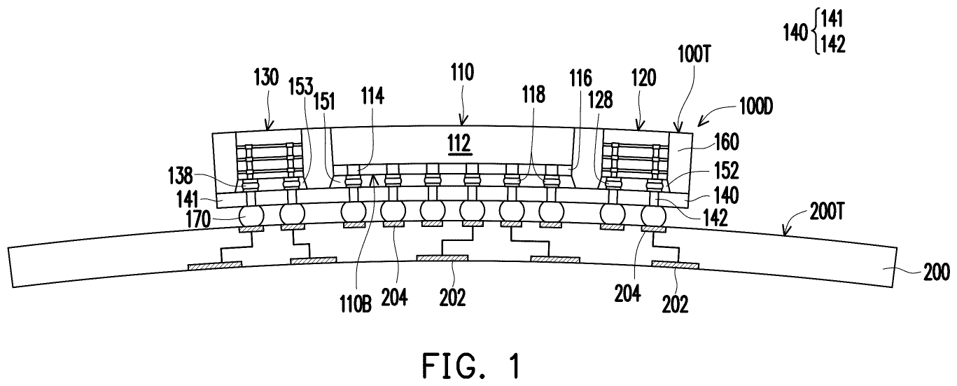

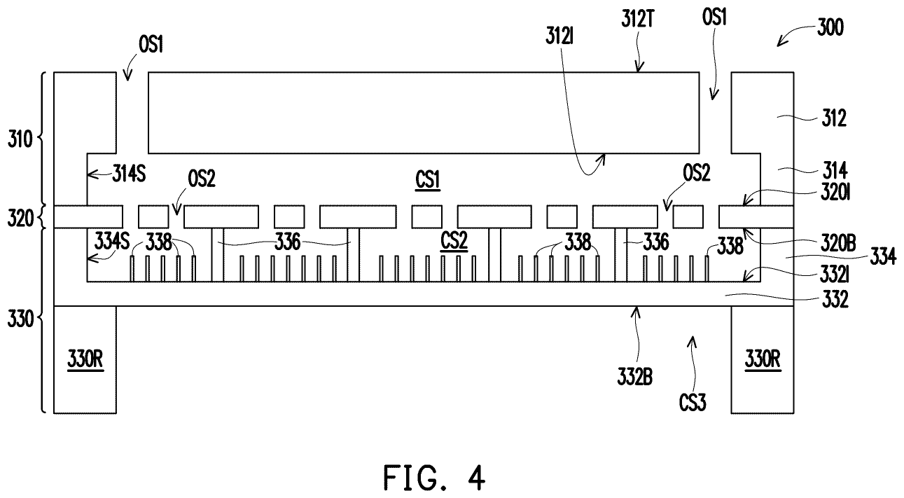

FIG. 1 through FIG. 5 are schematic cross-sectional views illustrating intermediate structures produced during a manufacturing method of a semiconductor package SD1 (shown in FIG. 4).

According to some embodiments of the present disclosure, referring to FIG. 1, a diced structure 100D is provided, and a substrate 200 is provided. In some embodiments, the diced structure 100D is mounted onto a top surface of the substrate 200 and bonded with the substrate 200 via connectors 170. In some embodiments, the diced structure 100D is a package unit including more than one dies, chips and/or electronic components. In some embodiments, the diced structure 100D is a package unit obtained from a reconstructed wafer structure with multiple dies or chips stacked on a substrate and undergoing a dicing process. In some embodiments, the diced structure 100D includes semiconductor dies 110, 120, 130 bonded to an interposer 140 through die connectors 118, 128, 138 respectively and laterally wrapped by an encapsulant 160. Herein, the diced structure may be referred to as a die structure or a die interchangeably.

In some embodiments, the semiconductor die 110 includes a semiconductor substrate 112, a plurality of contact pads 114 embedded in a passivation layer 116 on the semiconductor substrate 112. In some embodiments, the active surface 110B of the semiconductor die 110 where the contact pads 114 are exposed faces the interposer 140. In some embodiments, the semiconductor substrate 112 may be made of semiconductor materials, such as semiconductor materials of the groups III-V of the periodic table. In some embodiments, the semiconductor substrate 112 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, the semiconductor substrate 112 may include silicon on insulator (SOI) or silicon-germanium on insulator (SGOI). In some embodiments, the semiconductor substrate 112 includes active components (e.g., transistors, diodes, photodiodes, or the like) and optionally passive components (e.g., resistors, capacitors, inductors, fuses, or the like) formed therein. In certain embodiments, the contact pads 114 include aluminum pads, copper pads, or other suitable metal pads. In some embodiments, the passivation layer 116 may be a single layer of a suitable dielectric material or a multi-layered structure. In some embodiments, the die connectors 118, 128, 138 includes copper (Cu), copper alloys, gold, silver, solder materials or other conductive materials, and may be formed by deposition, plating, or other suitable techniques. In some embodiments, the die connectors 118, 128, 138 are prefabricated structures attached to the semiconductor dies 110, 120, 130 respectively. In some embodiments, the die connectors 118 are metal pillars, metal pillars with solder pastes, micro bumps, bumps formed via electroless nickel-electroless palladium-immersion gold technique (ENEPIG), or a combination thereof. In some embodiments, similar structural features as the ones just discussed for the semiconductor die 110 may be found in the other semiconductor dies of the diced structure 100D being formed (for example, in the semiconductor dies 120, 130 shown in FIG. 1A).

In some embodiments, each of the semiconductor dies 110, 120, 130 may independently be or include a logic die, such as a central processing unit (CPU) die, a graphic processing unit (GPU) die, a micro control unit (MCU) die, an input-output (I/O) die, a baseband (BB) die, or an application processor (AP) die. In some embodiments, each of the semiconductor dies 110, 120, 130 may independently be or include a photonic die, including optical components, such as waveguides, modulators, and lasers integrated in photonic integrated circuits. In some embodiments, one or more of the semiconductor dies 110, 120, 130 include at least one memory die such as a high bandwidth memory (HBM) die. In some embodiments, the semiconductor dies 110, 120, 130 may be different types of dies or perform different functions. In some embodiments, the semiconductor dies 110, 120, 130 may be the same type of dies or perform the same functions. In some embodiments, the semiconductor die 110 includes a logic die, and at least one of the semiconductor dies 120 and 130 includes a memory die.

In some embodiments, for the diced structure 100D, the interposer 140 includes a body 141 and through vias 142 penetrating through the body 141. Although not expressly depicted in the drawings, the interposer 140 may further includes redistribution layers (not shown) on either surface for redistributing or rerouting. For example, the body 141 is made from a dummy wafer of a semiconductor material, similarly to what was previously discussed with reference to the semiconductor substrate 112. In one embodiment, the interposer 140 is made from a silicon bulk wafer. In some embodiments, a material of the through vias 142 includes one or more metals. In some embodiments, the metal material of the through vias 142 may be copper (Cu), titanium (Ti), tungsten (W), aluminum (Al), the alloys, or the combinations thereof. In some embodiments, the semiconductor dies 110, 120, 130 are bonded via the die connectors 118, 128, 138 to the through vias 142 formed within the interposer 140. According to some embodiments, the semiconductor dies 110, 120, 130 are disposed with the active surfaces facing the interposer 140. In some embodiments, between the semiconductor dies 110, 120, 130 and the interposer 140, there are underfill materials 151, 152, 153 wrapping around the die connectors 118, 128, 138 to secure the electrical connection of the semiconductor dies 110, 120, 130 with the interposer 140 (bonded with the through vias 142). In some embodiments, the underfill 151, 152, 153 is formed by capillary underfill filling (CUF).

Referring to FIG. 1, in some embodiments, for the diced structure 100D, the semiconductor dies 110, 120, 130 are laterally wrapped around by the encapsulant 160 over the interposer 140. In some embodiments, the diced structure 100D is obtained by forming the encapsulant 160 over the interposer 140 covering the semiconductor dies 110, 120, 130 to form a reconstructed wafer structure (not shown), and then performing a wafer dicing process or a singulation process such as wafer dicing process. Optionally, a planarization process (e.g., a mechanical grinding process and/or a chemical mechanical polishing step) may be performed to remove extra encapsulant material until the backsides of the semiconductor dies 110, 120, 130 are exposed. In some embodiments, the material of the encapsulant 160 includes a resin material (such as an epoxy resin), a dielectric filling material or the like.

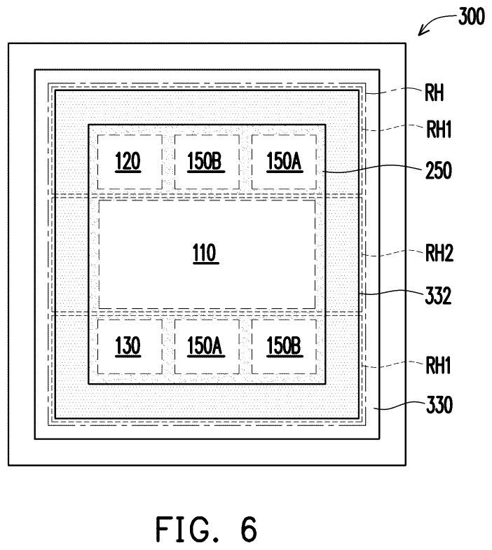

In FIG. 1 only three semiconductor dies 110, 120, 130 are shown on the interposer 140 for simplicity, but the disclosure is not limited thereto. In some embodiments, the diced structure 100D may include more or fewer semiconductor dies than what illustrated in the drawings, as well as other electronic devices or components (e.g., integrated passive devices (IPDs), micro-electronic-mechanical system (MEMS) devices, photonic devices etc.). In some embodiments, the diced structure 100D (in FIG. 6) further includes fourth dies 150A and fifth dies 150B, and the fourth dies 150A and fifth dies 150B are or include photonic dies/photonic devices. In FIG. 1, only a diced structure or package unit is shown for simplicity, however, the disclosure is not limited thereto. In some embodiments, multiple diced structures 100D are bonded onto the substrate 200 or the semiconductor package SD1 may include multiple diced structures or package units, as well as other electronic components and photonic integrated circuit components. Furthermore, whilst the process is currently being illustrated for a Chip-on-Wafer-on-Substrate (CoWoS) package, the disclosure is not limited to the package structure shown in the drawings, and other types of package such as integrated fan-out (InFO) packages, package-on-packages (PoP), etc., are also meant to be covered by the present disclosure and to fall within the scope of the appended claims. In some embodiments, the semiconductor package is a large-scale semiconductor package including photonic devices, and/or photonic modules.

In some embodiments, as illustrated in FIG. 1, the diced structure 100D is bonded to the top surface 200T of the substrate 200 via the connectors 170. In some embodiments, the substrate 200 includes connection structures 202 and 204 that are interconnected through internal routing layers (represented by the connecting lines) to achieve dual-side electrical connection. In some embodiments, the substrate 200 may be formed with a flexible polymeric material, and the substrate 200 is a flexible substrate. In some embodiments, the substrate 200 may be a package substrate or ball grid array (BGA) substrate that may include one or more active components and/or passive components therein and suitable connection among various components therein to form functional circuitry.

In some embodiments, as seen in FIG. 1, the diced structure 100D along with the substrate 200 are shown to be slightly deformed or warped (i.e. curved in a crying shape from the cross-sectional view), and the top surface 100T of the diced structure 100D at least includes a curved surface (e.g. an arched surface). Herein, the warpage form of the diced structure 100D shown in the drawings is intended to reflect the more realistic states or certain non-ideal states (i.e. the non-flat or twisted states) when the dimensions of the diced structure or the substrate are increasing and due to CTE mismatch among various materials. It is understood that the deformation or the state of warpage of the structure shown in the drawings is merely representative and exemplary, but not intended to limit the scope of this disclosure.

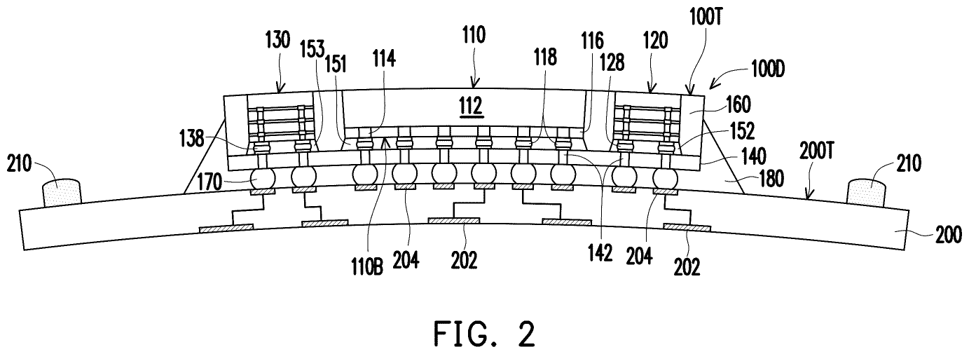

In some embodiments, referring to FIG. 2, an underfill 180 is formed between the diced structure 100D and the substrate 200, encircling the connectors 170 between the diced structure 100D and the substrate 200. For example, the underfill 180 may fill up the interstices among the connectors 170 and the gaps between the diced structure 100D and the substrate 200. In some embodiments, the underfill 180 outflows beyond the span of the diced structure 100D and extends to cover portions of the sidewall of the diced structure 100D. For instance, a material of the underfill 180 may include epoxy resins, phenolic resins, silica rubbers, or a combination thereof. In some embodiments, the underfill 180 is formed by capillary underfill filling (CUF). In some embodiments, the material of the underfill 180 may be different from the material for the underfills 151, 152, 153.

In some embodiments, referring to FIG. 2, a first bonding material 210 is disposed over the substrate 200, beside the diced structure 100D and around the diced structure 100D. In some embodiments, the first bonding material 210 may be formed after bonding the diced structure 100D to the substrate 200 and after the formation of the underfill 180. In some embodiments, the first bonding material 210 may be formed after bonding the diced structure 100D to the substrate 200 but before the formation of the underfill 180. In some embodiments, the first bonding material 210 is formed at locations beside the diced structure 100D and spaced apart from the diced structure 100D with a distance. In some embodiments, the first bonding material 210 is formed as an integral ring-shaped wall surrounding the diced structure 100D. In some embodiments, the first bonding material 210 is formed as separate lumps or globs arranged in a ring-shaped fashion around the diced structure 100D. Depending on the shape or the structure of to-be-mounted object (e.g. heat dissipation system), the arrangement and the distribution of the first bonding material 210 may be modified for assisting better adhesion and fixation of the later mounted object In some embodiments, the first bonding material 210 is disposed on the substrate 200 only where the heat dissipation system is expected to contact the substrate 200.

In some embodiments, the material of the first bonding material 210 includes thermo-curable adhesives, photocurable adhesives, thermally conductive adhesive, thermosetting resin, waterproof adhesive, lamination adhesive or a combination thereof. In some embodiments, the material of the first bonding material 210 includes a thermally conductive adhesive. Depending on the type of material used, the first bonding material 210 may be formed by deposition, lamination, printing, plating, or any other suitable techniques.

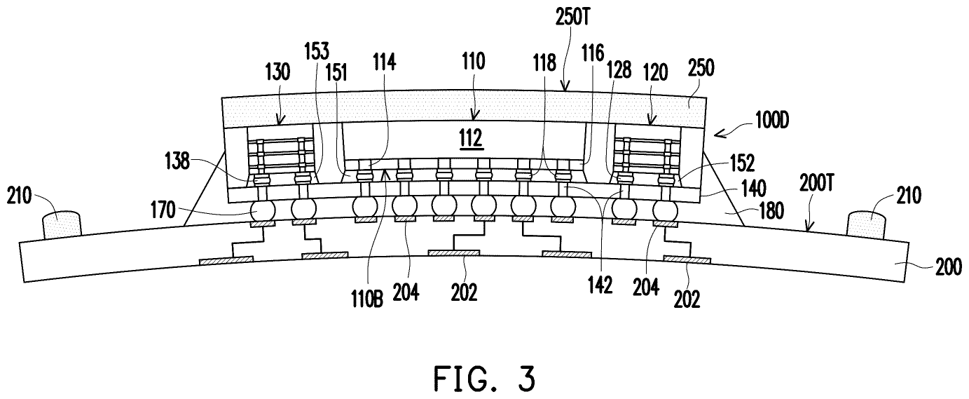

Referring to FIG. 3, in some embodiments, a second bonding material 250 is disposed on the back surface 100T over the diced structure 100D. In some embodiments, in FIG. 3, the second bonding material 250 is in contact with the back surface 100T of the diced structure 100D (i.e. in direct contact with the backside surfaces of the semiconductor dies 110, 120, 130 and the top surface of the encapsulant 160), while the top surface 250T of the second bonding material 250 is exposed. In some embodiments, the second bonding material 250 extends all over and covers the whole backside surfaces of the semiconductor dies 110, 120, 130 and the top surface of the encapsulant 160. In some embodiments, a span of the second bonding material 250 is about the same as or slightly larger than a span of the diced structure 100D. In some embodiments, the second bonding material 250 is formed with the ability to conform to the attached surface (i.e. the surface 100T) with a satisfactory coverage rate. That is, when the diced structure 100D is warped or deformed, the second bonding material 250 conformally formed thereon is also warped or deformed, and the surface 250T of the second bonding material similarly includes a curved surface (e.g. an arched surface), with a curvature (or warpage) fully conformal to the curvature (or warpage) of the curved top surface 100T of the diced structure 100D.

In some embodiments, the second bonding material is or includes a thermal interface material (TIM). In some embodiments, the TIM is or includes a film-type (or sheet-type) TIM containing one or more polymeric materials. In some embodiments, the film-type TIM may be applied by die-coating or rolling to the intended location and then laminated onto the diced structure 100D. In some embodiments, the film type TIM includes a polymeric adhesive material such as silicone or epoxy resins and thermally conductive fillers. For example, the thermally conductive fillers include metallic fillers of Cu, silver (Ag), tin (Sn), indium (In), or combinations thereof. For example, the materials of the thermally conductive fillers include boron nitride, aluminum (Al), aluminum oxide, aluminum nitride, Cu, Ag, In, or a combination thereof. In some embodiments, the film type TIM includes carbon nanotubes (CNT), graphite, or graphene. In certain embodiments, the film type TIM includes silicone-based polymer material and metallic fillers.

In some embodiments, the TIM is or includes or is a metal-type thermal interface material (metal-TIM), which includes only metals or metal alloys (without containing polymeric materials) and is highly thermally conductive. According to some embodiments of this disclosure, different types of metal-type thermal interface materials (metal-TIMs) are suitable to be used as the TIM or as the second bonding material 250, including solid type metal-TIMs (SMT) and liquid type metal-TIMs (LMT). In some embodiments, the TIM is applied in solid form as a film with a suitable thickness on the back surface 100T over the diced structure 100D. In some embodiments, the metal-TIM includes one or more metals from Sn, In, Ag, gallium (Ga), bismuth (Bi), zinc (Zn), or other suitable thermally conductive metals. In some embodiments, the metal-TIM includes Ga, gallium alloys, gallium-indium-tin alloys, gallium-indium-tin-zinc alloys, indium-bismuth-tin alloys. According to the type of material used, the metal-TIM may be formed by deposition, lamination, printing, plating, or any other suitable techniques. In some embodiments, the second bonding material 250 includes a phase-change material (PCM). In some embodiments, the second bonding material 250 includes a solder material, including Sn, In, Cu, Ag, Ga, Bi, rhodium (Rh), palladium (Pd), platinum (Pt), gold, or a combination thereof.

In some embodiments, the material of the second bonding material 250 is different from the material of the first bonding material 210. In some embodiments, the first bonding material 210 has a bonding strength (or adhesion strength) larger than that of the second bonding material 250, but the second bonding material 250 has a thermal conductivity higher than that of the first bonding material 210. The materials of the first or second bonding material are not particularly limited, and may be chosen as a function of the materials used for the to be mounted heat dissipation system which the first and second bonding materials have to secure together.

FIG. 4 is a schematic cross-sectional view showing a heat dissipation system according to some embodiments of this disclosure. Referring to FIG. 4, a heat dissipation system 300 is provided. In some embodiments, the heat dissipation system 300 includes a top cover 310, a middle plate 320 and a base plate 330. In some embodiments, the top cover 310 includes a cap portion 312 and a frame portion 314 that is at the border or periphery of the cap portion and joined with the cap portion 312 to support the cap portion 312. In some embodiments, the cap portion 312 has a plurality of vent holes OS1 formed therein, penetrating through the cap portion 312 and extending from the top surface 312T through the cap portion to the lower surface 312I. In some embodiments, the vent holes OS1 function as the inlet and outlet for the cooling fluid or coolant. In some embodiments, the middle plate 320 includes a plurality of through holes OS2 formed therein, penetrating through the middle plate 320 and extending from the upper surface 320I through the middle plate 320 to the lower surface 320B. In some embodiments, the base plate 330 includes a floor portion 332, a support portion 334 at the border or periphery of the floor portion 332 and a footing portion 330R connected with the floor portion 332. In some embodiments, the heat dissipation system 300 also includes flexible pillars 336 and fins 338 arranged on the upper surface 332I of the floor portion 332.

As seen in FIG. 4, upon assembly, the top cover 310 is connected with the middle plate 320, and a cavity or hollow space CS1 is defined between the top cover 310 and the middle plate 320 (e.g. between the surfaces 312I and 320I and inner sidewalls 314S of the frame portion 314). Similarly, the middle plate 320 is connected with the base plate 330, a cavity or hollow space CS2 is defined between the base plate 330 and the middle plate 320 (e.g. between the surfaces 332I and 320B and inner sidewalls 334S of the support portion 334). The top cover 310 connected with the middle plate 320 may be regarded as the upper plate or the upper portion of the heat dissipation system 300, while the base plate 330 connected with the middle plate 320 may be regarded as the lower portion of the heat dissipation system 300. In some embodiments, the flexible pillars 336 that are located within the space CS2 are joined with the floor portion 332 but with heights large enough to touch both surfaces 332I and 320B. In some embodiments, if the diced structure 100D is warped or deformed, the surface 332I is or includes a curved surface, some of the flexible pillars 336 may be slightly compressed or extended in order to adapt to the reduced or expanded room caused by the curved surface, so that the flexible pillars 336 present different heights. In some embodiments, communicating through the through holes OS2, the space CS1 and the space CS2 are interlinked and joined and function together as fluid circulation space. In some embodiments, the top cover 310 may constitute the ceiling and the walls of the circulation space CS1, and the base plate 330 may constitute the floor and the walls of the circulation space CS2. In some embodiments, the fins 338 that are also located within the space CS2 and arranged beside the flexible pillars 336 are joined with the floor portion 332, but the fins 338 are shorter than the flexible pillars 336 and do not touch the surface 320B. Upon the assembly, the footing portion 330R is located below the floor portion 332 and is connected to the lower surface 332B of the floor portion 332 at the border or periphery of the floor portion 332 to define an open space CS3.

In some embodiments, the vent holes OS1 and the through holes OS2 are open holes and may be shown to have a substantially vertical profile in the thickness direction in the drawings, and the sidewalls defining the spaces CS1 and CS2 may be shown as vertical sidewalls, but it is understood that either of these may have a slant profile or be a slant sidewall, and the disclosure is not limited thereto. Further details of the flexible pillars and the fins will be discussed later.

In some embodiments, the material of the heat dissipation system 300 has a high thermal conductivity and includes one or more metals or metallic materials, such as Cu, aluminum (Al), aluminum nitride (AlN), AlSiC, cobalt (Co), copper coated with nickel, nickel-iron alloys (e.g. Alloy 42), stainless steel (e.g. SUS430), tungsten (W), copper-tungsten alloys, copper-molybdenum alloys In some embodiments, the materials of the heat dissipation system 300 include an alloy of Cu, Al and Si, or aluminum silicon nitride (AlSiN), aluminum silicon carbide (AlSiC), Cu—AlSiC, Cu—AlSiN, or combinations thereof. In some embodiments, the heat dissipation system 300 is partially coated with another metal, such as gold, nickel, titanium-gold alloys or lead, tin, nickel, vanadium or combinations thereof. In some embodiments, the material of the heat dissipation system 300 has a high thermal conductivity and includes metal diamond composites (e.g. silver diamond, or copper diamond), diamond like carbon (DLC), single crystal diamond or combinations thereof. In some other embodiments, the material of the heat dissipation system 300 also includes super conductive materials such as metal diamond composites, including silver diamond (AgD), DLC, silver diamond composites, copper diamond composites, aluminum diamond composites, alloy 42 diamond composites, carbon metal composites, or a combination thereof. In some embodiments, a material of the lower portion of the heat dissipation system 300 includes aluminum silicon nitride (AlSiN), aluminum silicon carbide (AlSiC), Cu—AlSiC, Cu—AlSiN, or combinations thereof.

The formation of the heat dissipation system 300 including the top cover 310, the middle plate 320, and the base plate 330 may involve using various fabrication methods selected according to the material(s) chosen for t the top cover 310, the middle plate 320, and the base plate 330. In some embodiments, the top cover 310, the middle plate 320, and the base plate 330 may be formed by molding, forging, 3D-printing, plating, punching, or fabricated according to any other suitable techniques. In some embodiments, the top cover 310, the middle plate 320, and the base plate 330 are fabricated separately and then assembled to produce the system 300. Also, the flexible pillars 336 and the fins 338 may be prefabricated and installed to the base plate 330 or middle plate 320 of the system 300. Alternatively, the flexible pillars 336 and the fins 338 may be co-fabricated and integral to the base plate 330 or middle plate 320 of the system 300.

In some embodiments, the top cover 310, the middle plate 320 and the base plate 330 may be individually formed with uniform thickness or may present different thicknesses for various portions, as long as they are rigid enough to support the structures, to hold the spaces CS1, CS2 for fluid circulation and to maintain the space CS3 for accommodating the diced structure(s). For example, the floor portion 332 may present a thickness Tf when extending over the footing portion 330R before attached to the diced structure 100D, and the floor portion 332 with such thickness Tf is flexible and compliant enough to conform to the later attached diced structure 100D.

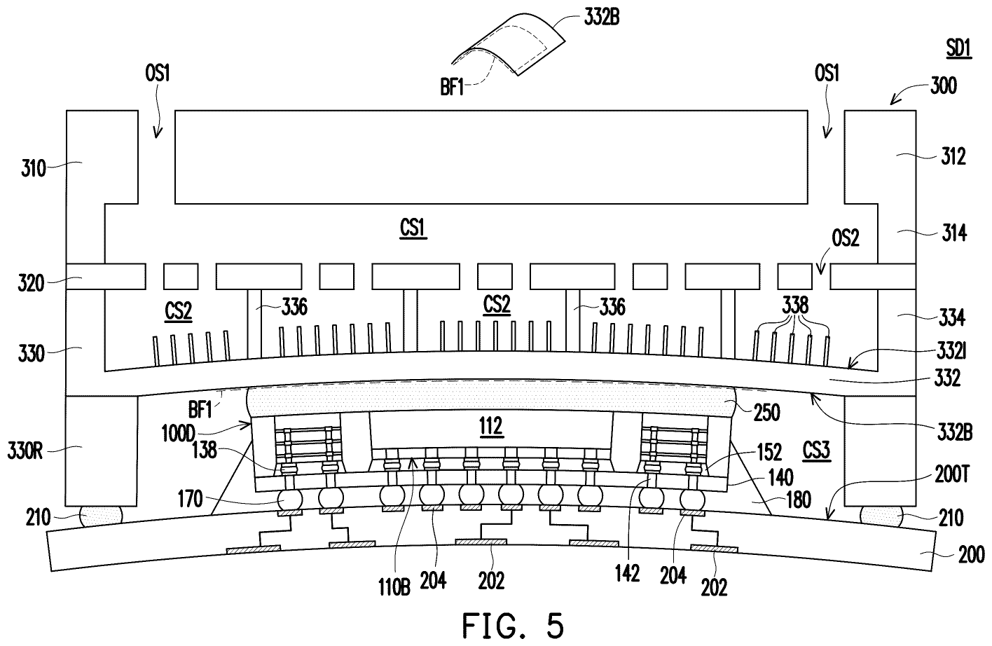

Referring to FIG. 5, through pick-and-place processes, the heat dissipation system 300 is disposed on the second bonding material 250 on the diced structure 100D over the substrate 200 so that the heat dissipation system 300 is aligned and mounted onto the diced structure 100D and the substrate 200. Later, a curing process is performed and the heat dissipation system 300 is attached to the diced structure 100D and the substrate 200. After the curing process, the heat dissipation system 300 is attached to the diced structure 100D through the second bonding material 250 and is fixed to and attached to the substrate 200 through the first bonding material 210, so that the semiconductor package SD1 is obtained. In some embodiments, the curing process is performed under the temperature ranging from about 100 degrees Celsius to about 300 degrees Celsius, preferably from about 130 degrees Celsius to about 190 degrees Celsius. Depending on the types of TIM(s) used, the curing temperature may be tuned.

It should be noted that from FIG. 1 through FIG. 5, the manufacturing of a single semiconductor package SD1 is shown for simplicity, but the disclosure is not limited thereto. In some embodiments, more than one diced structure(s) may be mounted on the substrate.

Herein, referring to FIG. 4 and FIG. 5, when the heat dissipation system 300 is attached to the diced structure 100D, the floor portion 332 is disposed on and in direct contact with the second bonding material 250 located on the diced structure 100D, and there is a bonding interface BF1 existing between the lower surface 332B of the floor portion 332 and the top surface 250T of the cured second bonding material 250. In FIG. 5, the floor potion 332 extends substantially parallel to the diced structure 100D and the substrate 200 (i.e. the bottom surface 332B extending substantially parallel to the top surface 100T of the diced structure 100D). Due to the designs of the flexible pillars 336 and the floor portion 332, the floor portion 332 is fully attached with the second bonding material 250 and is substantially conformal to the surface profile of the second bonding material 250 and the underlying diced structure 100D. As described above, the diced structure 100D (along with the substrate 200) may be slightly deformed or warped, and after the attachment, the floor portion 332 of the heat dissipation system 300 conforms to the warpage or deformation profile of the diced structure 100D. That is, the bonding interface BF1 is conformal to the warpage level of the diced structure 100D. As shown in the upper part of FIG. 5, it is seen that the bonding interface BF1 (as well as the bottom surface 332B of the floor portion 332) includes a curved surface (arched surface), with a curvature (or warpage) fully conformal to the curvature (or warpage) of the curved top surface 100T of the diced structure 100D. Herein, the curve or surface conformal to the other curve or surface refers to the angle or the size of the angle between corresponding curves or surfaces unchanged.

In some embodiments, when the warpage level of the dice structure 100D is significant, the base plate 330 may undergo curvature adjustment process, based on the predetermined curvature measured from prior processing batches or pre-measuring the dice structure.

As the floor portion 332 is conformally attached to the diced structure 100D, there is mainly no gaps or voids existing between the floor portion 332, the second bonding material 250 and the diced structure 100D. Hence, strong and reliable attachment and coverage of the heat dissipation system is established and higher thermal dissipation efficiency is achieved. In some embodiments, as the diced structure 100D is non-planar or warped, the floor portion 332 conforms to the profile changes and becomes non-planar or warped, and the second bonding material 250 sandwiched therebetween is non-planar or warped as well, and the second bonding material 250 establishes an excellent bonding interface with a very high coverage rate, showing substantially no voids or cracks upon the tests of the acoustic scanning microscope.

Referring to FIG. 5, when the heat dissipation system 300 is attached to the diced structure 100D through the second bonding material 250, the cap portion 312 and the middle plate 320 are disposed over the floor portion 332, extending across the diced structure 100D, and the footing portion 330R and the frame portion 314 and the support portion 334 respectively located at opposite sides and at the border of the middle plate 320 project towards the substrate 200. In some embodiments, the frame portion 314 is illustrated with a right angle at it joint to the cap portion 312, but the disclosure is not limited thereto. In some embodiments, the footing portion 330R and the support portion 334 respectively extend in a direction almost perpendicular to the planes defined by the surface 332B and the surface 332I, but different angles than 90 degrees may exist for the floor portion 332 may be curved or warped along with the diced structure 100D. In some embodiments, the footing portion 330R extends towards the substrate 200 and surrounds the diced structure 100D. In some embodiments, the footing portion 330R, the floor portion 332 and the substrate 200 define the space CS3 surrounding the diced structure 100D on all sides when the heat dissipation system 300 is attached to the substrate 200, and the diced structure 100D located within the space CS3 is spaced apart from the sidewalls of the footing portion 330R. In some embodiments, the span of the floor portion 332 extends beyond the span of the second bonding material 250 or the diced structure 100D. In some embodiments, the footing portion 330R reaches the substrate 200 where the first bonding material 210 is disposed, and the first bonding material 210 secures the heat dissipation system 300 within the semiconductor package SD1.

FIG. 6 is a schematic planar view illustrating the semiconductor package according to some embodiments of the present disclosure, and the planar view may be shown from a cross-section along the interface between the second bonding material 250 and the base plate 330. In some embodiments, referring to FIG. 6, a span (or distribution region) RH of the floor potion 332 where the flexible pillars 336 and the fins 338 are arranged exceeds a span (in solid line) of the second bonding material 250 or a span of the diced structure 100D. In some embodiments, the span of the second bonding material 250 or a span of the diced structure 100D may entirely fall within the span of the floor portion 332. In some embodiments, as shown in FIG. 6, depending on the types of dies and their respective thermal dissipation needs of the diced structure, the distribution region RH may be divided as first regions RH1 and a second region RH2. In some embodiments, if the die 110 is or includes a CPU die, the dies 120, 130 are or include memory dies, and the dies 150A, 150B are or includes photonic dies, as the CPU die may generate more heat (with a higher thermal design power (TDP)), the second region RH2 has a higher need for thermal dissipation and a higher TDP is needed when compared with the first regions RH1. Following such need, high thermal conductivity elements may be set in the region with a higher thermal dissipation need, and the arrangement and layouts of the fins may be changed accordingly.

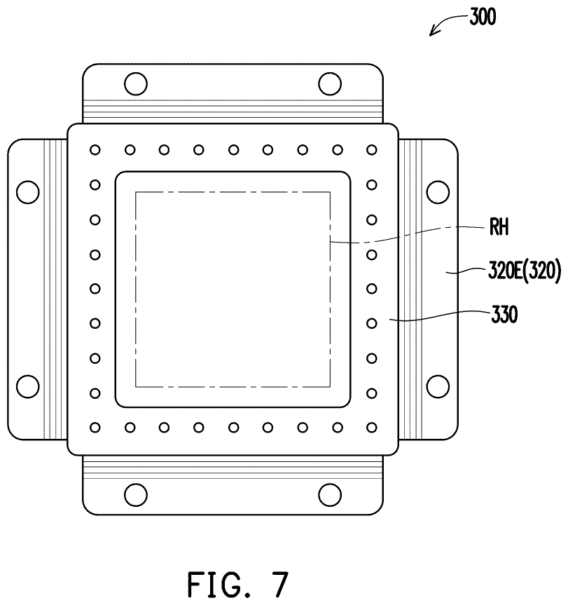

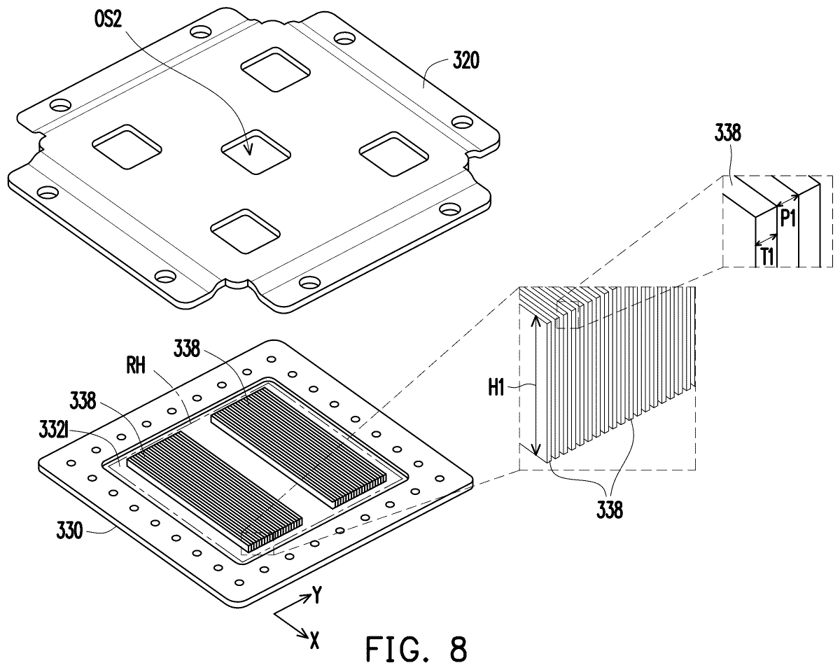

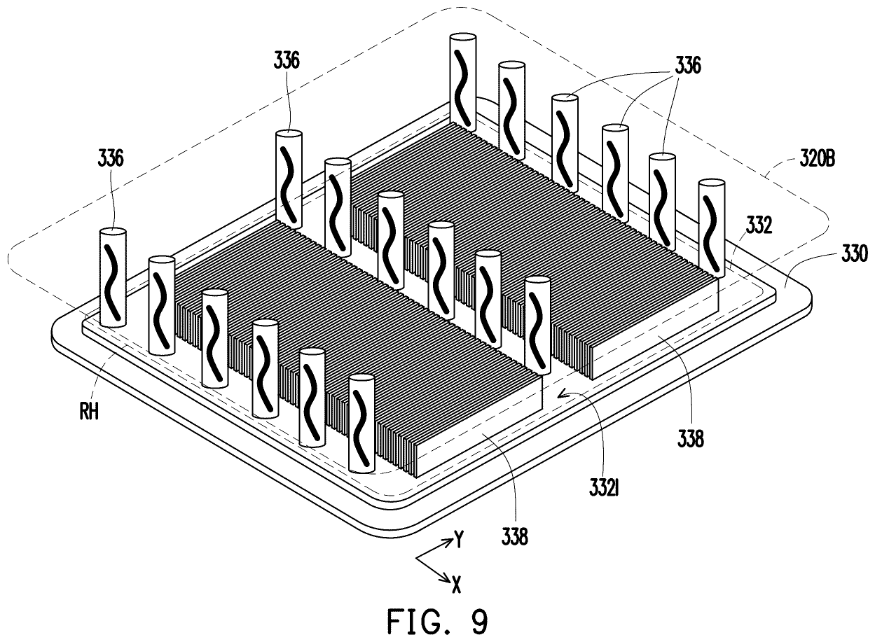

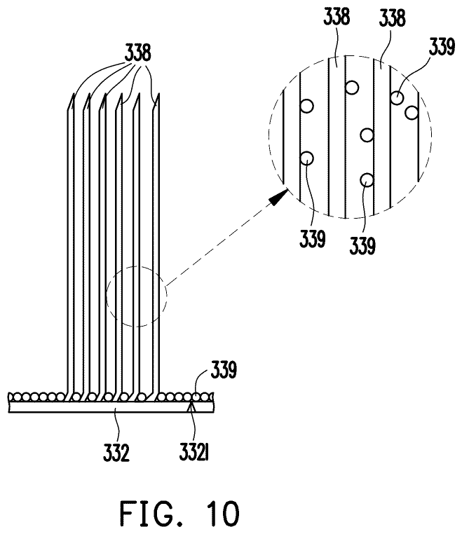

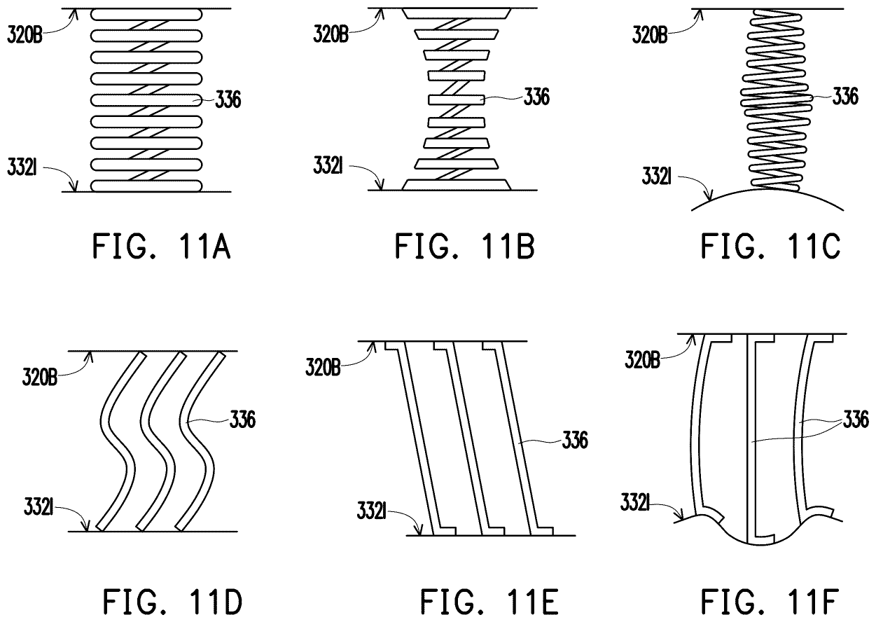

FIG. 7 is a schematic bottom view showing a portion of the heat dissipation system according to some embodiments of the present disclosure. FIG. 8 and FIG. 9 illustrate various portions of the heat dissipation system before assembly according to some embodiments of the present disclosure. FIG. 10 illustrates the skived fins within the heat dissipation system according to some embodiments of the present disclosure. FIG. 11A through FIG. 11F are schematic cross-sectional views of flexible pillars within the heat dissipation system according to some embodiments of the present disclosure.

Referring to FIG. 7, in some embodiments, upon assembly, the whole base plate 330 is overlapped with the middle plate 320, and auxiliary portions 320E protruding from the middle plate 320 and extending beyond the base plate 330 may be included for assisting the assembly or securement of the middle plate 320. In FIG. 7, the distribution region RH (in dashed line) is shown to be located in a middle or central portion of the floor portion 332 of the base plate 330. Referring to FIG. 8, the middle plate 320 and the base plate are shown to be separate from each other before assembly. In FIG. 8, it is seen that the middle plate 320 may be provided with multiple through holes OS2 as communicating passageways for the fluid flowing in the spaces CS1 and CS2. Also, in FIG. 8, the fins 338 are parallel strip-shaped thin projections protruding upward from the surface 332I and extending in the X-direction, and the fins 338 are evenly spaced apart from each other along the Y-direction with a pitch P1. Alternatively, in FIG. 9, the fins 338 are parallel strip-shaped thin projections protruding upward from the surface 332I and extending in the Y-direction, and the fins 338 are evenly spaced apart from each other along the X-direction. In some embodiments, the fins 338 are extending in parallel and in a direction parallel to the flow direction of the circulating coolant during the functioning of the heat dissipation system. In some embodiments, referring to FIG. 8, the fins 338 may be formed of substantially the same dimensions with the same height H1 and the same thickness T1. For example, the thickness T1 of the fins 338 ranges from about 50 microns to about 200 microns, the pitch P1 ranges from about 100 microns to about 200 microns, and the height H1 ranges from 1 mm to about 5 mm. In some embodiments, the material of the fins 338 includes a highly thermally conductive material. In some embodiments, the material of the fins 338 includes one or more metals or metal alloys, such as Cu, Al, alloys thereof, the combinations thereof. In certain embodiments, the material of the fins 338 includes AlSiN, AlSiC, Cu—AlSiC, Cu—AlSiN, or combinations thereof.

In FIG. 8 and FIG. 9, the thin fins 228 are fixed onto the inner surface 332I of the floor portion 332 of the base plate 330 and are distributed as two groups or sections within the distribution region RH. Referring to FIG. 10, a boiling enhancement coating 339 may be included within the heat dissipation system 300 coated on the inner surface 332I of the floor portion 332 among the fins 338 and on the surfaces of the fins 338 as well. In some embodiments, the boiling enhancement coating 339 may be distributed over the whole distribution region RH. In some embodiments, the boiling enhancement coating 339 may be distributed only over the fin sections within the distribution region RH. Depending on the thermal dissipation needs, the boiling enhancement coating 339 may be distributed only in the region that has a higher thermal dissipation need. In some embodiments, the boiling enhancement coating 339 includes powders, meshes, twills, foam or grooved wicks of one or more metals, alloys or metallic materials. In some embodiments, the materials of the boiling enhancement coating 339 includes Cu, Al, Ni, Ti, Ag, stainless steel, sintered metals thereof, alloys thereof, or combinations thereof. In some embodiments, the boiling enhancement coating 339 includes nickel powders, copper powders, aluminum powders, and stainless-steel powders (containing Ag, Cu-phosphorous alloys). In some embodiments, the boiling enhancement coating 339 includes copper powders of diameters ranging from about 10 microns to about 50 microns. In certain embodiments, the copper powders are sintered under 800°C.-1000°C., and optionally with pores smaller than 10 microns. In some embodiments, the boiling enhancement coating 339 includes wicks, metallic wire meshes or twills made of Cu, stainless steel, or Monel with microporous sintered metal powder coatings. In some embodiments, the boiling enhancement coating 339 includes one or more porous metals and/or glass fibers.

Referring to FIG. 9, the flexible pillars 336 are fixed onto the inner surface 332I of the floor portion 332 of the base plate 330 and are arranged in columns alongside both sections of the fins 338 (with in the distribution region RH). In some embodiments, the flexible pillars 336 with heights large enough to touch both surfaces 332I and 320B are joined to the inner surface 332I of the floor portion 332 and the lower surface 320B of the middle plate 320, functioning as the height adjustment elements. As seen from FIG. 11A, FIG. 11B and FIG. 11C, the flexible pillars 336 may have different configurations and may be formed in a form of a coil or a spring such as the helical spring pillar (FIG. 11A) with a contact pitch, the hourglass shaped helical spring pillar (FIG. 11B), or a barrel shaped helical spring pillar (FIG. 11C). As seen in FIG. 11C, if the surface 332I is or includes a curved surface, the flexible pillar 336 may be slightly compressed in order to adapt to the curved surface, due to the nature of the spring structure. Alternatively, as seen in from FIG. 11D, FIG. 11E and FIG. 11F, the flexible pillars 336 may be formed in a form of S-shaped pillars (FIG. 11D), Z-shaped pillars (FIG. 11E) or C-shaped pillars (FIG. 11F). In some embodiments, in FIG. 11F, if the surface 332I is or includes a wavy (wave-shaped curly or undulatingly curved) surface, the flexible pillars 336 may be slightly compressed or extended to present different heights in order to adapt to the reduced or expanded room caused by the curved surface. In some embodiments, the materials and the configurations of the flexible pillars 336 are carefully chosen to provide enough springiness or flexibility, so that the heights of the flexible pillars 336 may be fine-tuned in order to adapt to the possibly non-planar surface upon the mounting of the heat dissipation system 300 onto the underlying diced structure. For example, the flexible pillars 336 may have a spring load (force) of about 10 g to about 500 g. In some embodiments, the material of the flexible pillars 336 includes a resilient and thermally conductive material. In some embodiments, the material of the flexible pillars 336 includes one or more metals or metal alloys, such as Cu, Al, AlSiN, AlSiC, Cu—AlSiC, Cu—AlSiN, alloys thereof, or combinations thereof.

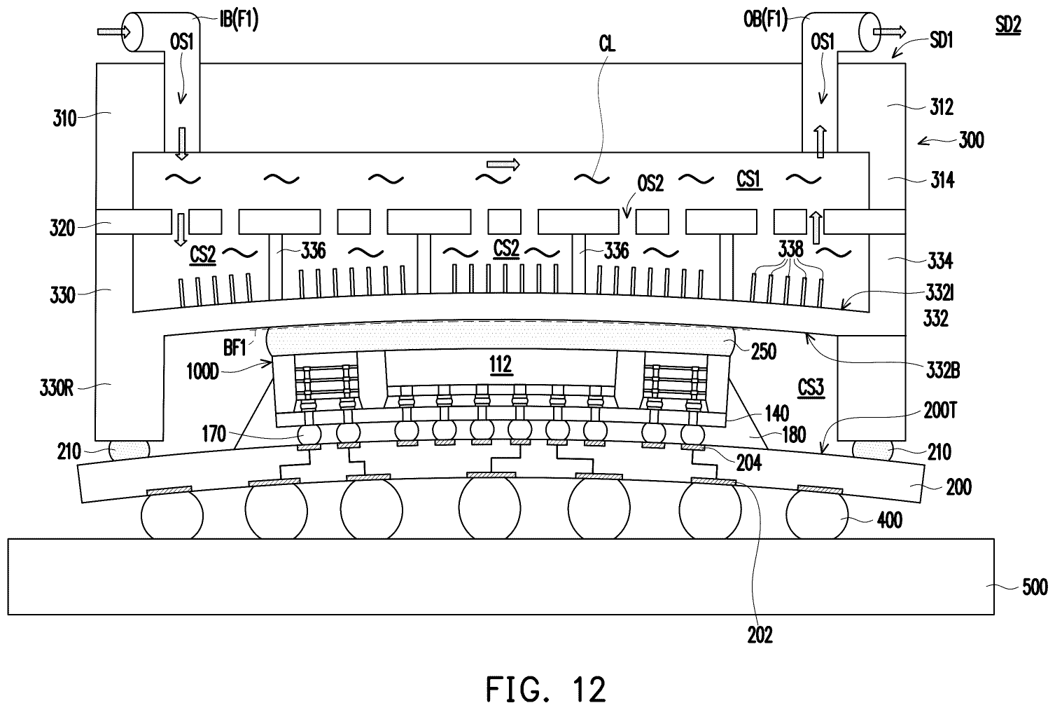

FIG. 12 is a schematic cross-sectional view showing an electronic device according to some embodiments of the present disclosure. In the electronic device of FIG. 12, the semiconductor package SD1 of FIG. 5 is further connected to a circuit substrate 500 with a fluid circulation system according to some embodiments of the disclosure.

In some embodiments, referring to FIG. 5 and FIG. 12, the electronic device SD2 is obtained by mounting the semiconductor package SD1 as described in FIG. 5 onto a circuit substrate 500 and the semiconductor package SD1 is electrically connected to the circuit substrate 500 through the connectors 400 located therebetween. In some embodiments, a fluid circulation system F1 including an inlet tube IB and an outlet tube OB is connected with the heat dissipation system 300, and the inlet tube IB and the outlet tube OB are respectively installed within the vent holes OS1 of the top cover 310, so that the vent holes OS1 function as the inflow/outflow channels in fluid communication with the circulation space CS1 as well as the circulation space CS2 (communicating via the through holes OS2). In some embodiments, the coolant CL flows from the inlet tube IB through the inflow/outflow channels OS1 into the circulation space CS1, flowing into the circulation space CS2, where it flows through the fins 338 and the flexible pillars and transferring heat, flowing back into the space CS1 and then flowing through the channels OS1, and finally flows out from the outlet tube OB (flow directions shown by arrows). Upon the action of the heat dissipation system 300, the heat that is generated from the diced structure 100D is transferred through the second bonding material 250 to the heat dissipation system 300, further transferred by the coolant circulating in the heat dissipation system 300 and then dissipated out of the heat dissipation system 300 to an outer environment. As explained in further detail below, the coolant CL flowing through the circulation spaces CS1 and CS2, especially the space CS2, flows through the fins 338 and through the surface 332I (flowing over the boiling enhancement coating 339) to transfer and bring the heat through the circulation path and flows out of the heat dissipation system 300 from the outlet tube OB. In some embodiments, the coolant CL is or includes water. In some embodiments, the coolant CL is or includes a dielectric liquid. In some embodiments, additives are added to the water to produce a cooling fluid. Examples of additives include surfactants, corrosion inhibitors, biocides, antifreeze, and the like.

As the base plate 330 (i.e. floor portion 332) conformally covers the diced structure 100D and the second bonding material 250, there is no void or cracks at the bonding interface BF1 such conformity or compliance leads to an excellent heat transfer interface and results in high thermal dissipation efficiency for the heat dissipation system 300. In some embodiments, as mentioned above, in certain regions on the surface 332I or within the circulation space CS2, the boiling enhancement coating 339 is coated on the surface 332I and distributed over the surfaces of the fins 338, at locations over one or some of the semiconductor dies that produce the greatest amount of heat during operation of the semiconductor package SD1. Upon the circulation of the coolant CL, two phase cooling may occur when the coolant flows through the boiling enhancement coating 339, and the coolant CL is boiled from the liquid state into the gas state by the heat transferred, which further enhances the thermal dissipation efficiency.

In some embodiments, the flexible pillars 336 and the fins 338 that are interspersed within the circulation space CS2 define a network of interstices in fluidic communication without interrupting the fluidic communication within the space CS2, among the circulation spaces CS1 and CS2, or the inflow and outflow of the coolant CL.

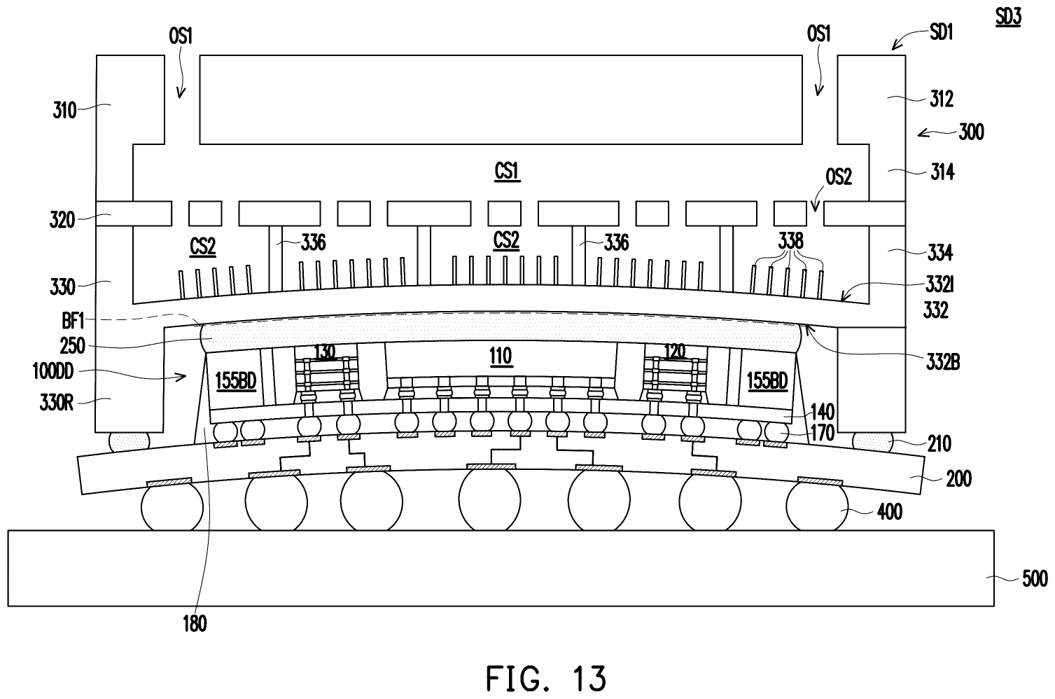

FIG. 13 is a schematic cross-sectional view showing another electronic device according to some embodiments of the present disclosure. In the electronic device of FIG. 13, the semiconductor package is further connected to a circuit substrate 500 with a fluid circulation system according to some embodiments of the disclosure.

In some embodiments, referring to FIG. 13, for the electronic device SD3, the semiconductor package SD1′ is similar to the semiconductor package SD1 described in FIG. 5, except for the diced structure 100DD is different. The main difference between the diced structure 100D and the diced structure 100DD lies in that the diced structure 100DD further includes photonic dies 155BD integrated with the diced structure 100D, and the photonic dies 155BD and the diced structure 100D are partially wrapped by the underfill 180.

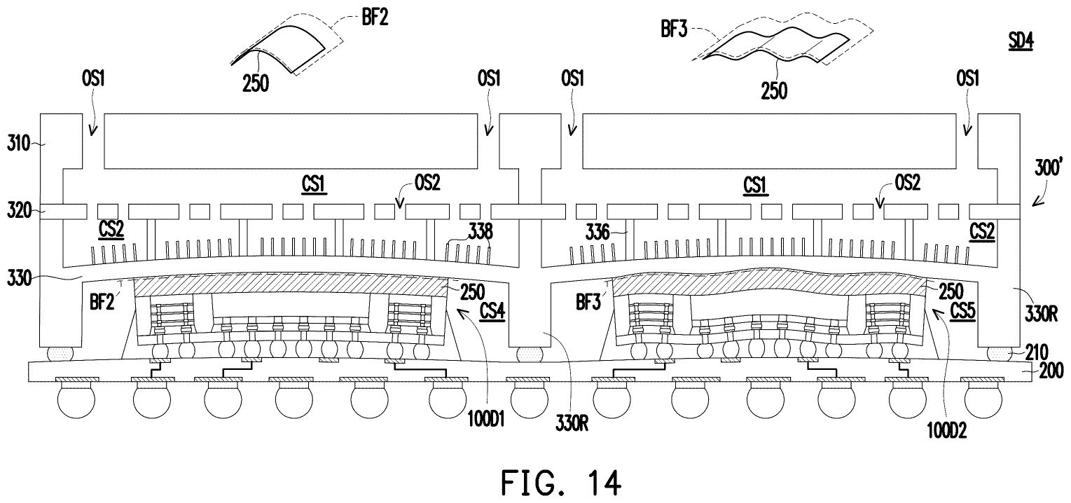

FIG. 14 is a schematic cross-sectional view of a semiconductor package according to some embodiments of the present disclosure. In FIG. 14, the semiconductor package SD4 is similar to the semiconductor package SD1 described in FIG. 5, except for at least two diced structures 100D1 and 100D2 are connected to the substrate 200, and the footing portion 330R of the heat dissipation system 300′ defines at least two spaces or cavities CS4 and CS5 respectively accommodating the diced structures 100D1 and 100D2. As seen in FIG. 14, the diced structures 100D1 and 100D2 present different warpage levels. In the left upper part of FIG. 14, the diced structure 100D1 is deformed or warped (i.e. curved in a crying shape from the cross-sectional view), and the bonding interface BF2 between the base plate 330 of the heat dissipation system 300′ and the second bonding material 250 on the diced structure 100D1 at least includes a curved surface (e.g. an arched surface). In the right upper part of FIG. 14, the diced structure 100D2 is deformed in a wavy form (i.e. curved in a wavy shape from the cross-sectional view), and the bonding interface BF3 between the base plate 330 of the heat dissipation system 300′ and the second bonding material 250 on the diced structure 100D2 at least includes several curved surfaces (e.g. wavy and curvy surfaces). It is seen that the base plate of the heat dissipation system is compliant and conforming to the surface profiles or topology of the below diced structures, and excellent thermal dissipation interfaces are established, leading to excellent thermal performance.

It will be apparent to people skilled in the art that the disclosure is not limited by the type of package used in the semiconductor packages. For all the semiconductor packages of the present disclosure, different types of packages (CoWoS, InFO, PoP, etc.) may be applicable, according to the production and design requirements.

The heat dissipation system disclosed herein is rather versatile, and may be applied to different types of semiconductor packages with only minor adjustments. Furthermore, features of the specific embodiments illustrated above may be combined in multiple ways, and all these ways are meant to fall within the scope of the present disclosure and the attached claims. As a non-limiting example, in some embodiments of the disclosure, the heat dissipation system may be modified to have shape adjustments and/or additional parts including flanges, fixture, or fastening elements for easy assembly.

Based on the above, a semiconductor package according to the present disclosure may include a die and a heat dissipation system disposed on the die through thermal interface material disposed in between. In some embodiments, the heat dissipation system is conforming to the warpage or deformation of the below die(s) through curvature adjustment of the base plate and through the height adjustment elements, so that a satisfactory thermal transfer interface is established.

In some embodiments of the present disclosure, a semiconductor package is provided. The semiconductor package includes a substrate, a die, a first bonding material, a second bonding material and a heat dissipation system. The die is disposed on and connected to the substrate. The die has a first surface and a second surface opposite to the first surface. The first bonding material is disposed on the substrate and beside the die. The second bonding material is disposed on the second surface of the die, covering the second surface of the die. The heat dissipation system, having a bottom surface in contact with the second bonding material, is disposed on the second bonding material over the die, and is disposed on the first bonding material on the substrate. The heat dissipation system is fixed to the substrate through the first bonding material. The bottom surface of the heat dissipation system is fixed to the die through the second bonding material with a bonding interface existing between the second bonding material and the bottom surface of the heat dissipation system, and the bonding interface includes a first curved surface.

In some embodiments of the present disclosure, a semiconductor package is provided. The semiconductor package includes a die, a first bonding material, a second bonding material and a heat dissipation system. The die is disposed on and is connected to a substrate with a first surface of the die facing the substrate. The die includes a first semiconductor die and a second semiconductor die. The first bonding material is disposed on the substrate and beside the die. The second bonding material is disposed on the die, covering a second surface of the die opposite to the first surface, and covering the first and second semiconductor dies. The heat dissipation system is disposed on the second bonding material over the die, and disposed on the first bonding material on the substrate. The heat dissipation system includes an upper portion and a lower portion connected to the upper portion and including a floor portion. A bottom surface of the floor portion is in contact with the second bonding material, and the bottom surface includes a first curved surface. The second surface of the die includes a second curved surface, and the first curved surface is conformal to the second curved surface.

In some embodiments of the present disclosure, a manufacturing method of a semiconductor package is provided. The manufacturing method includes the following steps. A die having a first surface and a second surface opposite to the first surface is provided. The die includes a first semiconductor die and a second semiconductor die. The die is connected to a substrate so that the first surface of the die faces the substrate. A first bonding material is disposed on the substrate. A second bonding material is disposed on the second surface die covering the first and second semiconductor dies. A heat dissipation system is provided. The heat dissipation system is disposed on the second bonding material over the die and on the first bonding material on the substrate, so that a bottom surface of the heat dissipation system is in contact with the second bonding material. A curing process is performed to bond the heat dissipation system with the die through the second bonding material, so that the heat dissipation system is fixed to the substrate through the first bonding material, and the bottom surface of the heat dissipation system is attached to the die through the second bonding material. A bonding interface exists between the second bonding material and the bottom surface of the heat dissipation system, and the bonding interface includes a first curved surface.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor package, comprising:
a substrate;
a die, disposed on and connected to the substrate, wherein the die has a first surface and a second surface opposite to the first surface;
a first bonding material disposed on the substrate and beside the die;
a second bonding material disposed on the second surface of the die, covering the second surface of the die; and
a heat dissipation system, having a bottom surface in contact with the second bonding material, disposed on the second bonding material over the die, and disposed on the first bonding material on the substrate,
wherein the heat dissipation system is fixed to the substrate through the first bonding material and the bottom surface of the heat dissipation system is fixed to the die through the second bonding material with a bonding interface existing between the second bonding material and the bottom surface of the heat dissipation system, and the bonding interface includes a first curved surface.

2. The semiconductor package of claim 1, wherein the second surface of the die includes a second curved surface, and the first curved surface is conformal to the second curved surface.

3. The semiconductor package of claim 1, wherein the heat dissipation system includes a base plate having a floor portion extending over the second bonding material and covering the die, and a footing portion joined with the floor portion and extending from the floor portion to the first bonding material, and the die is located below the floor portion and surrounded by the footing portion.

4. The semiconductor package of claim 3, wherein the heat dissipation system includes a middle plate disposed over the base plate, the base plate includes a support portion disposed between the middle plate and the floor portion to define a circulation space between the support portion, the middle plate and the floor portion.

5. The semiconductor package of claim 4, wherein the heat dissipation system includes parallel fins joined to the floor portion and located within the circulation space, and flexible pillars joined to the floor portion and the middle plate and located beside the fins.

6. The semiconductor package of claim 5, wherein the bottom surface includes a third curved surface conformal to the second curved surface, and the flexible pillars located on the floor portion have different heights.

7. The semiconductor package of claim 5, wherein the fins extend parallelly to a flow direction of a coolant circulating in the circulation space.

8. The semiconductor package of claim 1, wherein a material of the heat dissipation system includes alloys of aluminum, silicon and copper, aluminum silicon nitride (AlSiN), aluminum silicon carbide (AlSiC), Cu—AlSiC, Cu—AlSiN, or combinations thereof.

9. A semiconductor package, comprising:
a die, disposed on and connected to a substrate, wherein the die has a first surface and a second surface opposite to the first surface, and the die includes a first semiconductor die and a second semiconductor die;
a first bonding material disposed on the substrate and beside the die;
a second bonding material disposed on the second surface of the die, covering the second surface of the die and covering the first and second semiconductor dies; and
a heat dissipation system, disposed on the second bonding material over the die, and disposed on the first bonding material on the substrate, wherein the heat dissipation system includes an upper portion and a lower portion connected to the upper portion and including a floor portion, a bottom surface of the floor portion is in contact with the second bonding material, and the bottom surface includes a first curved surface,
wherein the second surface of the die includes a second curved surface, and the first curved surface is conformal to the second curved surface.

10. The semiconductor package of claim 9, wherein the bottom surface of the floor portion is in contact with a top surface of the second bonding material, and the top surface of the second bonding material includes a third curved surface conformal to the first and second curved surfaces.

11. The semiconductor package of claim 9, wherein the heat dissipation system includes parallel fins joined to the floor portion, and flexible pillars joined to the floor portion and located beside the fins.

12. The semiconductor package of claim 11, wherein the flexible fins located on a top surface of the floor portion opposite to the bottom surface have different heights.

13. The semiconductor package of claim 11, wherein a boiling enhancement coating is included on a top surface of the floor portion.

14. The semiconductor package of claim 13, wherein the boiling enhancement coating is coated on surfaces of the fins.

15. The semiconductor package of claim 13, wherein the first semiconductor die has a power consumption higher than that of the second semiconductor die, and the boiling enhancement coating is distributed over a first region of the floor portion that is located directly above the first semiconductor die.

16. The semiconductor package of claim 9, wherein a material of the lower portion of the heat dissipation system includes aluminum silicon nitride (AlSiN), aluminum silicon carbide (AlSiC), Cu—AlSiC, Cu—AlSiN, or combinations thereof.

17. A manufacturing method of a semiconductor package, comprising:
providing a die having a first surface and a second surface opposite to the first surface, wherein the die includes a first semiconductor die and a second semiconductor die;
connecting the die to a substrate so that the first surface of the die faces the substrate;
disposing a first bonding material on the substrate;
disposing a second bonding material on the second surface die covering the first and second semiconductor dies;
providing a heat dissipation system;
disposing a heat dissipation system on the second bonding material over the die and on the first bonding material on the substrate, so that a bottom surface of the heat dissipation system is in contact with the second bonding material; and
performing a curing process to bond the heat dissipation system with the die through the second bonding material, so that the heat dissipation system is fixed to the substrate through the first bonding material, and the bottom surface of the heat dissipation system is attached to the die through the second bonding material,
wherein a bonding interface exists between the second bonding material and the bottom surface of the heat dissipation system, and the bonding interface includes a first curved surface.

18. The manufacturing method of claim 17, wherein the second surface of the die includes a second curved surface, and the first curved surface is conformal to the second curved surface.

19. The manufacturing method of claim 17, wherein the heat dissipation system is provided with flexible pillars joined to an interior surface of the heat dissipation system opposite to the bottom surface.

20. The manufacturing method of claim 19, wherein the bottom surface includes a third curved surface conformal to the second curved surface, and the flexible pillars have different heights.
